(19) United States
(12) Patent Application Publication
(10) Pub. No.: US 2009/0250432 A1
(43) Pub. Date: Oct. 8, 2009

(54) Method of controlling plasma distribution uniformity by time-weighted superposition of different solenoid fields

(76) Inventors: Daniel J. Hoffman, Saratoga, CA (US); Ezra Robert Gold, Sunnyvale, CA (US); Douglas H. Burns, Saratoga, CA (US); Douglas A. Buchberger, JR., Livermore, CA (US); Michael Charles Kutney, Santa Clara, CA (US); Jang Gyoo Yang, Sunnyvale, CA (US)

Correspondence Address: LAW OFFICE OF ROBERT M. WALLACE, 2112 EASTMAN AVENUE, SUITE 102, VENTURA, CA, 93003, US

(21) Appl. No.: 12/082,074

(22) Filed: Apr. 7, 2008

(51) Int. Cl. H01L 21/3065; C23C 16/513

(52) U.S. Cl. 216/68; 427/569

(57) ABSTRACT

A method of processing a workpiece in a chamber of a plasma reactor having a set of plural electromagnet coils includes selecting plural predetermined plasma density distributions relative to a workpiece surface, the predetermined plasma density distributions corresponding to different sets of D.C. currents in the coils, and flowing a process gas into the chamber and generating a plasma in the chamber. The method further includes switching plasma in the chamber between the predetermined plasma density distributions by switching D.C. currents through the coils between the different sets of D.C. currents.

### BACKGROUND

Plasma processing of workpieces such as semiconductor wafers to form nanometer-sized thin film features requires precise control over plasma uniformity. Improving device performance requires decreasing feature sizes, which increases requirements for plasma ion density distribution uniformity across the surface of a workpiece or wafer. Using two axially displaced solenoidal coils over a plasma reactor chamber, plasma distribution can be changed by changing the D.C. currents applied to the coils.

Plasma ion density distribution non-uniformity has been reduced to as low as 5% (the measured variance or standard deviation) by choosing the D.C. currents in the overhead solenoidal coils. The problem is that nonuniformity must be reduced even further, and it has not seemed possible to reduce the uniformity below 5%.

### SUMMARY

A method is provided for processing a workpiece in a chamber of a plasma reactor having a set of plural solenoidal electromagnet coils. The method includes selecting plural predetermined plasma density distributions relative to a workpiece surface, wherein the predetermined plasma density distributions correspond to different sets of D.C. currents in the solenoidal coils, and flowing a process gas into the chamber and generating a plasma in the chamber. The method further includes switching plasma in the chamber between the predetermined plasma density distributions by switching D.C. currents through the solenoidal coils between the different sets of D.C. currents. In one embodiment, the predetermined plasma density distributions have different non-uniformities that are at least partially mutually compensating. In one embodiment, the method further includes time-weighting the predetermined plasma density distributions by controlling the respective time durations the plasma spends in the respective ones of the predetermined plasma density distributions. The time-weighting may be adjusted to optimize uniformity of process rate distribution at the workpiece surface.

In another embodiment, the plural predetermined plasma density distributions are two-dimensional and the different non-uniformities of the predetermined distributions include azimuthal non-uniformities and radial non-uniformities. The azimuthal non-uniformities of the predetermined distributions may be at least partially mutually compensating and the radial non-uniformities of the predetermined distributions may be at least partially mutually compensating.

In one embodiment, the switching of D.C. currents in the solenoidal coils between the different sets of D.C. currents is carried out by changing the currents in all of the solenoidal coils for each transition between the predetermined distributions. In one embodiment, the switching of D.C. currents in the solenoidal coils between the different sets of D.C. currents is carried out by changing (a) the magnitudes of the currents in at least some of the solenoidal coils and (b) the polarities of the currents in at least some of the solenoidal coils. In one embodiment, the switching of D.C. currents in the solenoidal coils between the different sets of D.C. currents is carried out by reversing polarities of the currents in all of the solenoidal coils for each transition between the predetermined distributions.

### BRIEF DESCRIPTION OF THE DRAWINGS

So that the manner in which the exemplary embodiments of the present invention are attained and can be understood in detail, a more particular description of the invention, briefly summarized above, may be had by reference to the embodiments thereof which are illustrated in the appended drawings. It is to be appreciated that certain well known processes are not discussed herein in order to not obscure the invention.

FIG. 1A is a simplified block diagram of a plasma reactor system in accordance with one embodiment.

FIG. 1B depicts a simplified implementation of a process controller of the reactor of FIG. 1A.

FIG. 2 is a graph depicting the behavior of plasma distribution non-uniformity as a function of overhead coil current.

FIG. 3 is a graph depicting the radial components of center-high and center-low plasma distributions and a composite distribution obtained by their superposition.

FIG. 4 is a graph depicting the azimuthal components of different plasma distributions and a composite distribution obtained by their superposition.

FIG. 5A is a graph representing a two-dimensional plasma distribution obtained by a first set of D.C. currents applied to the overhead coils.

FIG. 5B is a graph representing a two-dimensional plasma distribution obtained by a second set of D.C. currents applied to the overhead coils.

FIG. 5C is a graph representing a net plasma distribution corresponding to a measured etch rate distribution obtained by switching the coil currents between the two sets of currents corresponding to the distributions of FIGS. 5A and 5B for a predetermined duty cycle.

FIG. 5D is a graph depicting the separate radial components of the plasma distributions of FIGS. 5A, 5B and 5C.

FIG. 6 is a block flow diagram of a simplified process implemented by the process controller of the reactor of FIG. 1A.

FIG. 7 is a block flow diagram of a comprehensive process including an optimization search method which the process controller of FIG. 1A may be programmed to execute.

FIGS. 8A and 8B constitute a block diagram depicting a method in accordance with another embodiment.

FIGS. 9A, 9B, 9C and 9D are graphs depicting interpolations employed in carrying out certain portions of the method of FIGS. 8A and 8B.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

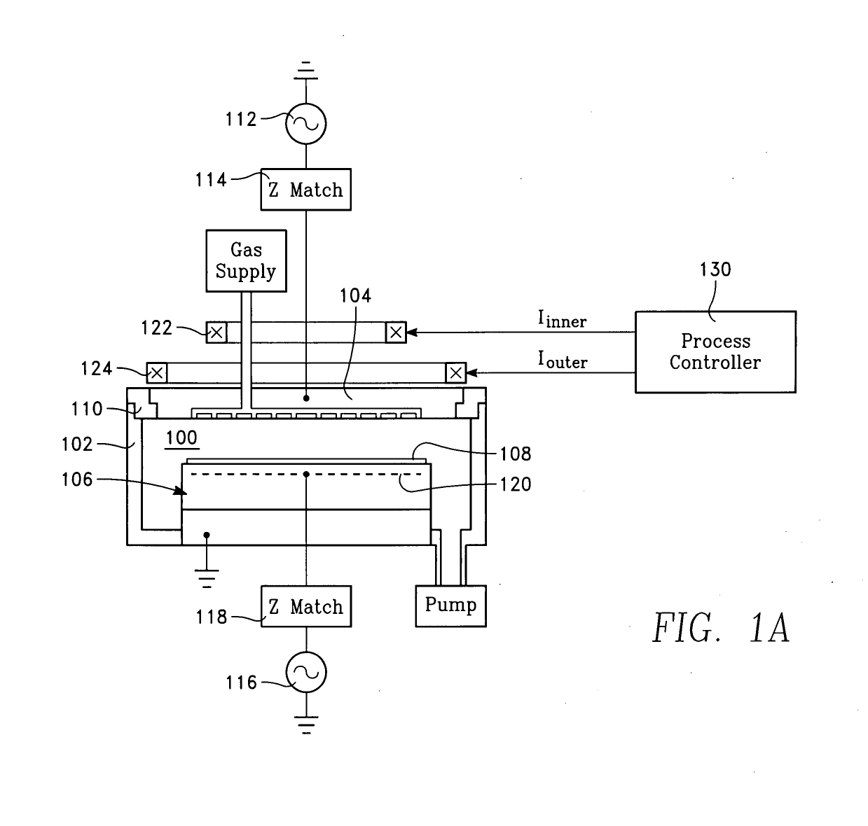

Referring to FIG. 1A, a plasma reactor includes a chamber 100 defined by side walls 102, a ceiling 104 and a workpiece support 106 within the chamber for supporting a workpiece or wafer 108 to face the ceiling 104. An plasma source power applicator, which may be adapted to couple power such as RF plasma source power into the chamber is provided. The plasma source power applicator may be any suitable form, such as a coil antenna (not shown) overlying the ceiling 104, an electrode formed by the ceiling 104 as shown in FIG. 1A, a toroidal plasma source or other sources such as a microwave source, a Helicon source, etc. In FIG. 1A, the ceiling 104 is formed of metal to provide an electrode as the RF plasma source power applicator, and an insulating ring 110 separates the ceiling electrode 104 from the side wall 102. An RF source power generator 112 provides RF plasma source power through an impedance match element 114 to the ceiling electrode 104. An RF bias power generator 116 provides RF plasma bias power through another impedance match element 118 to an electrode 120 within the workpiece support 106. A pair of inner and outer solenoidal electromagnet coils 122, 124 overlie the reactor chamber 100, the coils 122, 124 being of different diameters and at different axial locations, as shown in FIG. 1A. In the embodiment of FIG. 1A, the inner coil 122 is disposed at a higher axial location than the outer coil 124, although an opposite arrangement may be employed. Also, the number of solenoidal coils may exceed two. Furthermore, while the solenoidal coils 122, 124 are depicted as being mutually coaxial and coaxial with the axis of symmetry of the reactor chamber 100, other arrangements not involving such symmetries may be employed.

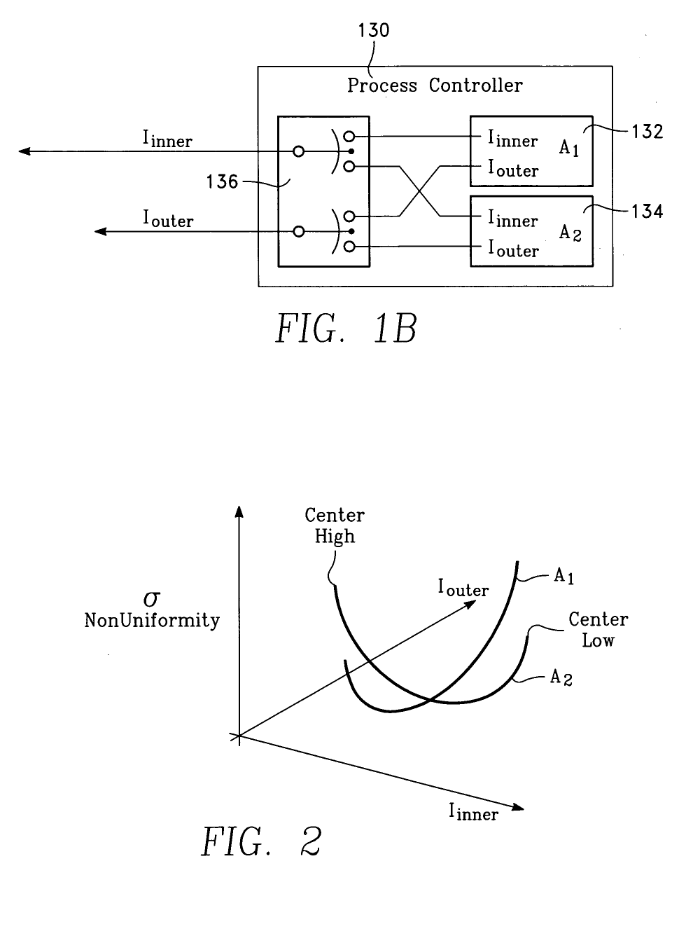

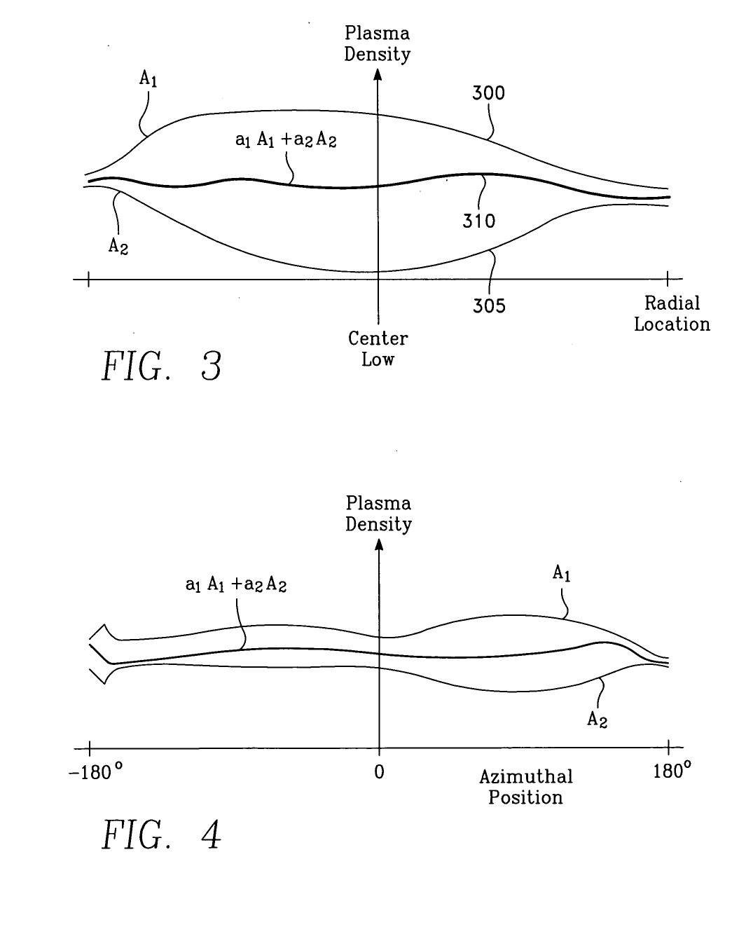

FIG. 2 depicts the behavior of the non-uniformity or variance, σ, in plasma ion distribution (vertical axis) as a function of D.C. currents Iᵢₙₙₑᵣ, Iₒᵤₜₑᵣ (x and y horizontal axes) in the two coils 122, 124. At a low current level in each coil, the plasma ion distribution tends to be highly non-uniform, the non-uniformity corresponding to a center high distribution, such as the center-high radial distribution 300 in the graph of FIG. 3. At a high current, the plasma ion distribution tends to be high non-uniform, the non-uniformity corresponding to a center-low distribution, such as the center-low distribution in 305 in the graph of FIG. 3. At some intermediate current in each coil, the non-uniformity is minimum. The location of the trough or ideal operating point of minimum non-uniformity in FIG. 2 is typically difficult or impractical to locate. Therefore, in one embodiment, the ideal behavior at the minimum uniformity or trough in the graph of FIG. 2 is obtained by switching the coil currents between two sets of values corresponding to two distributions A₁ and A₂ fairly near but on opposite sides of the trough. The net effect over time corresponds to a superposition of the center-high and center-low distributions 300, 305 of FIG. 3, resulting in an intermediate distribution 310 that is neither center-high nor center-low and therefore more uniform.

The switching of the coil currents Iᵢₙₙₑᵣ, Iₒᵤₜₑᵣ to switch the plasma between the distributions A₁ and A₂ is performed by a programmed process controller 130 of the reactor of FIG. 1A. In one embodiment, the process controller 130 includes a microprocessor programmed to perform the methods described below in this specification. A simplified representation of the controller 130 is depicted in FIG. 1B, in which the controller 130 governs current flow from two sources 132, 134 of respective current pairs that produce the plasma ion distributions A₁ and A₂. The distributions A₁ and A₂ are depicted in FIG. 3 as radial distributions (functions of radius r). The controller 130 further has a switching element 136 that switches the respective coils 122, 124 between the corresponding output pairs of the two sources. The switching element 136 may be programmable to spend a duty cycle, a₁, connected to the A₁ current source 132 and a duty cycle, a₂, connected to the A₂ current source 134, where

a₁+a₂=1

and

a₂=|1−a₁|.

The controller 130 generates a time-weighted superposition of the two plasma distributions A₁ and A₂ (the distributions 300, 305 of FIG. 3) to produce the intermediate distribution 310, which may be defined as the time-weighted superposition or combination

A_{comb}=a₁A₁+a₂A₂

The time-weights or coefficients a₁ and a₂ can be chosen to minimize the non-uniformity or variance in A_{comb}.

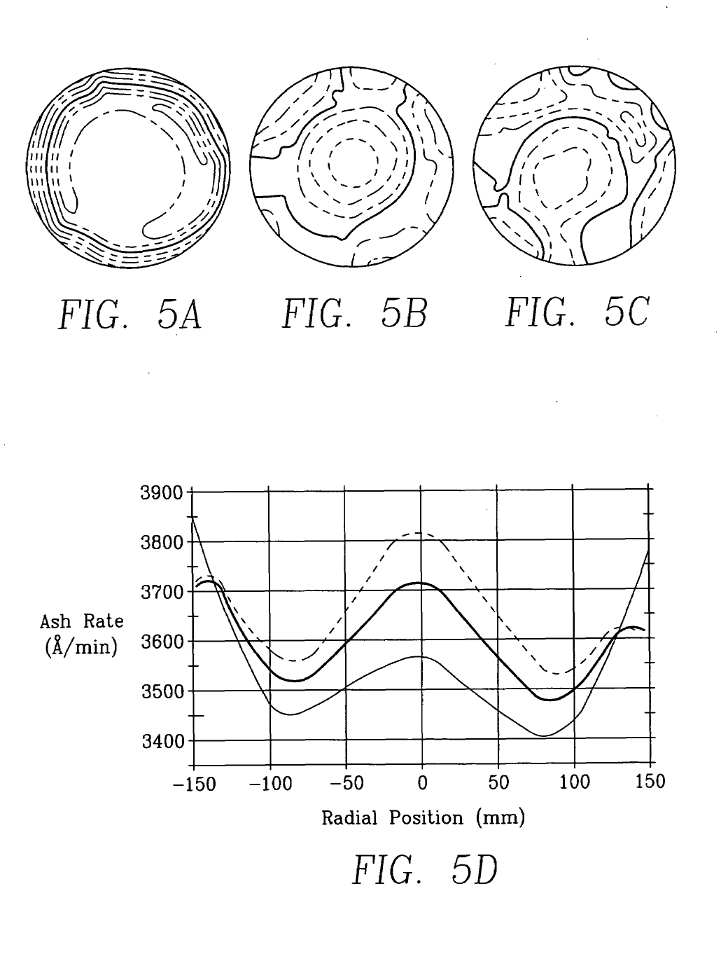

The distributions A₁ and A₂ may be two-dimensional, so that what is depicted in FIG. 3 are their radial components. For the two-dimensional case, the azimuthal components of the distributions A₁ and A₂ are depicted in FIG. 4 as functions of angle θ.

More than two solenoidal coils may be employed. More than two different plasma distributions may be included in the time-weighted superposition or combination A_{comb}.

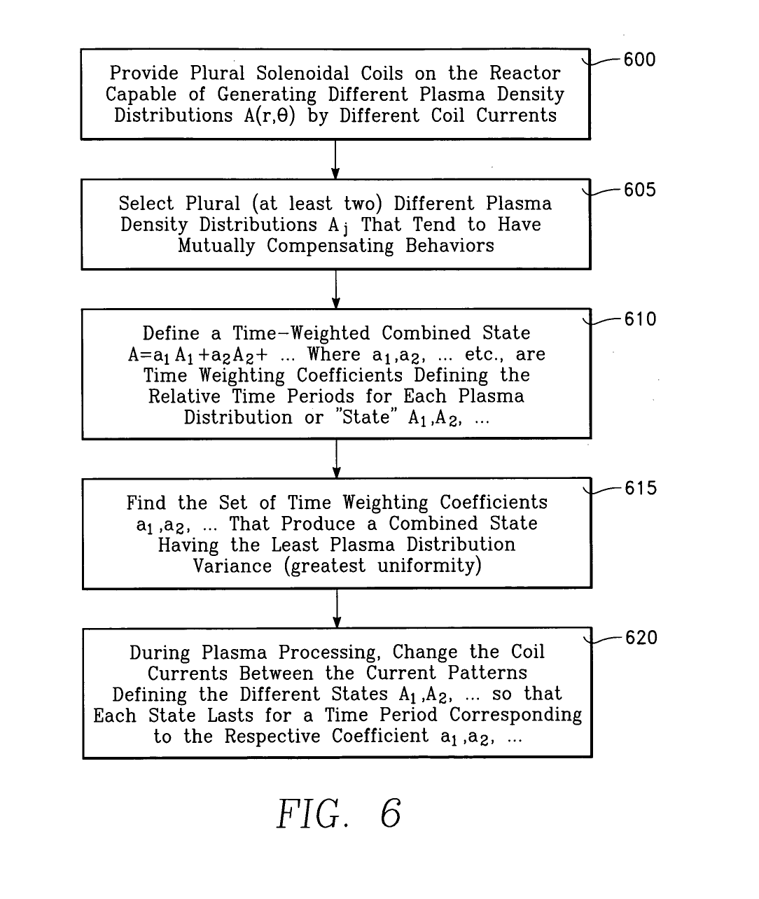

FIGS. 5A-5D depict a working example. In FIG. 5A, the D.C. coil currents Iᵢₙₙₑᵣ, Iₒᵤₜₑᵣ are set to produce a center-low two-dimensional plasma ion density distribution A₁ depicted in FIG. 5A. Specifically, Iᵢₙₙₑᵣ=−8 amps and Iₒᵤₜₑᵣ=+10 amps. In FIG. 5B, the D.C. coil currents Iᵢₙₙₑᵣ, Iₒᵤₜₑᵣ are set to produce a center-high two-dimensional plasma ion density distribution A₂ depicted in FIG. 5B. Specifically, Iᵢₙₙₑᵣ=0 amps and Iₒᵤₜₑᵣ=0 amps. The distribution A₁ had a deviation between maximum and minimum density values of 7.7% and a variance σ=4.7%. The distribution A₂ had a deviation between maximum and minimum density values of 5.9% and a variance σ=2.5%. The time duration or weighting coefficient a₁ was 38.8% while the time duration or weighting coefficient a₂ was 61.2%. The resulting effective combined distribution A_{comb} depicted in FIG. 5C had a maximum-to-minimum deviation of only 3.9% and a very low variance σ=1.8%. FIG. 5D compares the radial components of the two-dimensional distributions A₁ (solid line), A₂ (dashed line) and A_{comb} (thick line). The plasma distributions A₁, A₂, and A_{comb} were obtained by measuring etch rate distributions across the surfaces of test wafers.

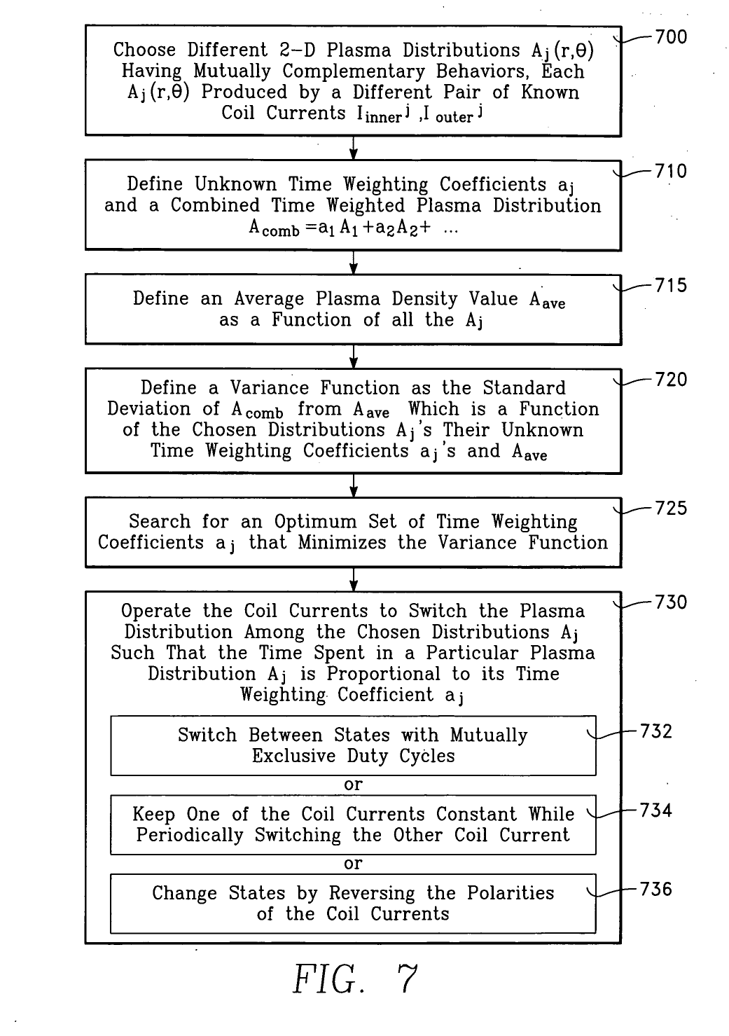

A method for carrying out an embodiment is depicted in FIG. 6. The programmable process controller 130 of FIG. 1A may be programmed to carry out the method of FIG. 6. In this case, the controller 130 may include machine-readable media storing instructions for carrying out the steps of FIG. 6. In the method of FIG. 6, the reactor is provided with plural solenoidal coils capable of generating different plasma ion density distributions by changing the D.C. currents through the coils to different values (block 600 of FIG. 6). Two different plasmas distributions (A₁ and A₂) are chosen, tending to have different shapes that may compensate for non-uniformities inherent in each other (block 605). Unknown time weighting coefficients a₁, a₁ are defined and a combined time weighted plasma distribution A_{comb}=a₁ A₁+a₂ A₂ is defined (block 610). A search is made to find the set of time weighting coefficients a₁, a₂ that minimizes plasma distribution variance or maximizes uniformity (block 615). How this search process is performed is discussed below in this specification. During plasma processing, the processor 130 changes the coil currents between the coil current pairs that generate the different distributions or states A₁ and A₂ so that each state lasts for a time period corresponding to the respective coefficient a₁, a₂ (block 620).

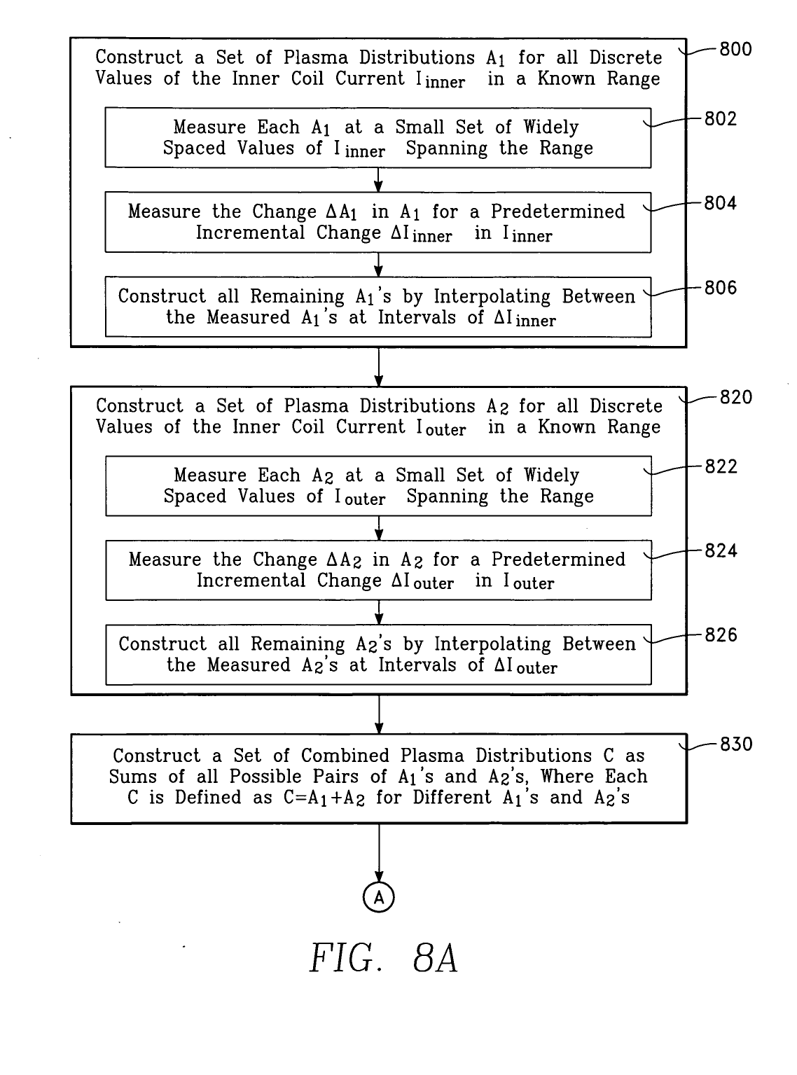

FIG. 7 depicts a method employing any number (two or more) of different plasma distributions that are two dimensional. The programmable process controller 130 of FIG. 1A may be programmed to carry out the method of FIG. 7. In this case, the controller 130 may include machine-readable media storing instructions for carrying out the steps of FIG. 7. The method of FIG. 7 includes a method for optimizing the time weighting coefficients a₁ and a₂. First, two (or more) different two-dimensional (2-D) plasma distributions are chosen (block 700 of FIG. 7). Each of these distributions may be designated as Aⱼ(r,θ) in cylindrical coordinates relative to the surface of the workpiece or wafer. The index or subscript “j” identifies a particular one of the chosen distributions. Preferably, the different distributions have mutually complementary behaviors. Each distribution Aⱼ(r,θ) is produced by a different pair of known coil currents Iᵢₙₙₑᵣ^{j}, Iₒᵤₜₑᵣ^{j} which are stored in a memory of the controller 130. Unknown time weighting coefficients aⱼ are defined and a combined time weighted plasma distribution A_{comb}=a₁ A₁+a₂ A₂+ . . . is defined (block 710). An average plasma density value Aₐᵥₑ is defined as a function of all the chosen Aⱼ (block 715), which in one embodiment may be in accordance with the following equation:

$${A}_{ave} = {\sum }_{j = 1}^{n} {\int }_{0}^{R} {\int }_{0}^{2 π} {a}_{j} \cdot {A}_{j} \cdot d r \cdot d θ$$

where aⱼ is the time duration of plasma distribution Aⱼ and R is the radius of the wafer to be plasma processed.

A variance function is defined as the standard deviation of A_{comb} from Aₐᵥₑ which is a function of the chosen distributions Aⱼ's, their unknown time weighting coefficients aⱼ's and Aₐᵥₑ (block 720). This variance function in one embodiment may be defined in accordance with the following equation:

$$σ = {[ \frac{1}{{A}_{ave}} {\int }_{0}^{R} {\int }_{0}^{2 π} \frac{1}{R} {( {\sum }_{j = 1}^{n} {a}_{j} {A}_{j} - {A}_{ave} )}^{2} d r \cdot d θ ]}^{1 / 2}$$

This formula is used by the controller 130 to search for an optimum set of time weighting coefficients aⱼ that minimizes the variance function σ (block 725 of FIG. 7). Such as search may be constructed by the skilled worker in view of the foregoing teachings using standard mathematical programming practices. A number of mathematical programs are readily available that the skilled worker can employ to find the optimum values of the time weighting coefficients, the aⱼ's.

After the optimum time weighting coefficients have been found, the solenoidal coil currents are switched between the sets of currents corresponding to the chosen distributions Aⱼ such that the time spent in a particular plasma distribution Aⱼ is proportional to its time weighting coefficient aⱼ (block 730). This switching operation may be performed in any one of the following modes.

In a first mode, the coil currents are switched between sets of currents defining successive chosen distributions Aⱼ (block 732). That is, the currents are switched between states in mutually exclusive duty cycles.

In a second mode, one of the coil currents is maintained at a constant level another coil current is switched between different values (block 734).

In a third mode, the plasma is switched to between two chosen distributions by reversing the polarities of the coil currents (block 736).

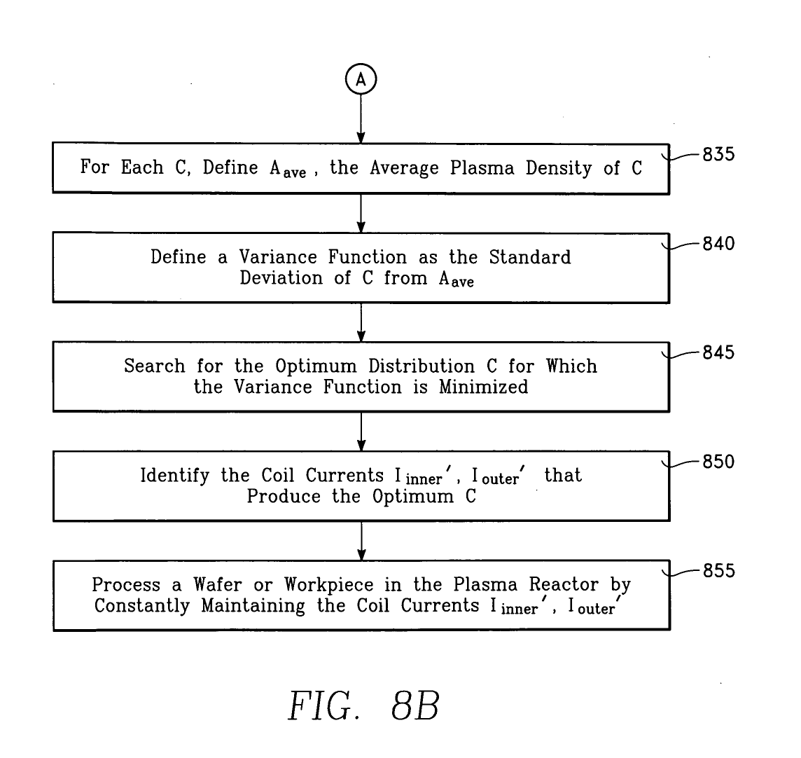

FIGS. 8A and 8B constitute a flow diagram illustrating a method in which the coil currents Iᵢₙₙₑᵣ, Iₒᵤₜₑᵣ are held constant rather than being switched, and a search is made for the optimum pair of constant coil currents Iᵢₙₙₑᵣ′, Iₒᵤₜₑᵣ,′ that produces an ideal plasma distribution A′ having the least variance or non-uniformity. The programmable process controller 130 of FIG. 1A may be programmed to carry out the method of FIGS. 8A and 8B. In this case, the controller 130 may include machine-readable media storing instructions for carrying out the steps of FIGS. 8A and 8B.

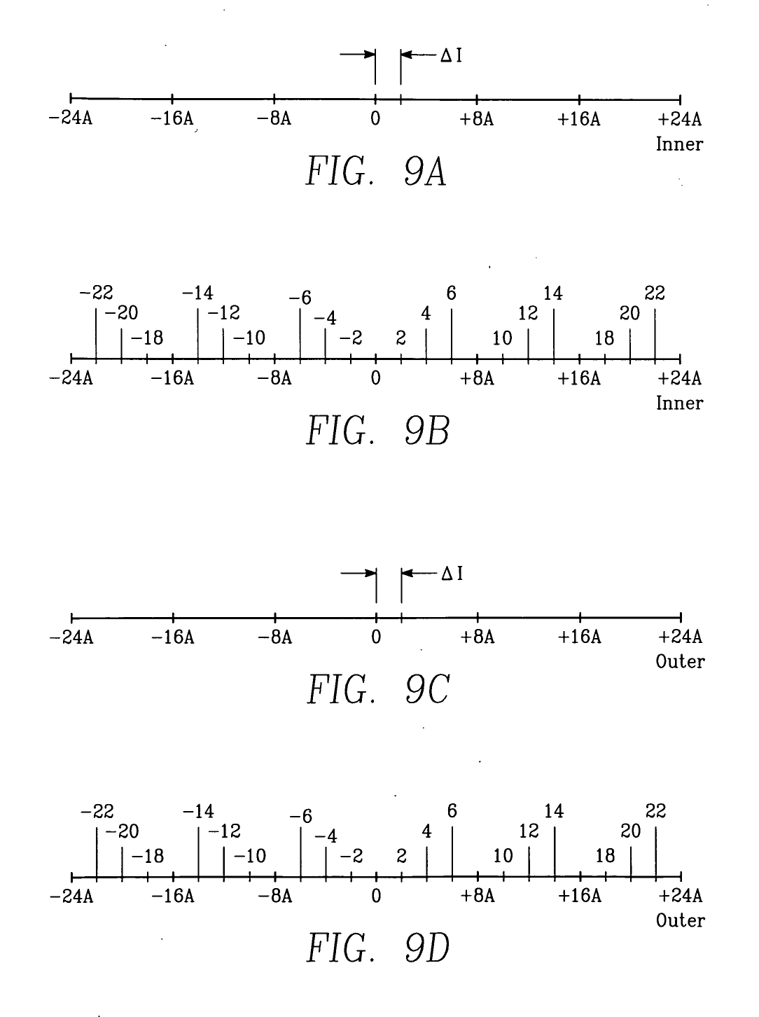

Referring to FIGS. 8A and 8B, in block 800, a set of plasma distributions A₁ is constructed for all discrete values of Iᵢₙₙₑᵣ in a predetermined range. (The subscript “1” refers to the inner coil.) This is carried out as follows. First, in block 802, a reduced number of plasma distributions A₁ are measured at a small set of widely spaced values of Iᵢₙₙₑᵣ spanning the chosen range. One example of this step is depicted in FIG. 9A, in which the chosen range is −24 amps to +24 amps, and the values of Iᵢₙₙₑᵣ occur in steps of ΔIᵢₙₙₑᵣ=4 amps, so that only twelve measurements are taken. Each of the twelve measurements is carried out by etching a test wafer while holding the current on the inner coil at one of the twelve values of Iᵢₙₙₑᵣ and then deducing the two-dimensional plasma distribution A₁ from the etch depth distribution on the test wafer, and storing the corresponding two-dimensional distribution A₁. The result is a set of twelve measured inner coil plasma distributions A₁. Then, in block 804, a measurement is made to determine the change ΔA₁ in plasma distribution A₁ for a predetermined incremental change ΔIᵢₙₙₑᵣ=4 amps in the coil current Iᵢₙₙₑᵣ. This determination may be made while Iᵢₙₙₑᵣ=0. In one embodiment, it is assumed that the distribution change ΔA₁ is the same regardless of location within the range −24 amps to +24 amps. The distribution change ΔA₁ may be found by subtracting any two measured plasma distributions A₁ generated by inner coil currents that differ by 4 amps. For example, ΔA₁, A₈ₐₘₚₛ−A₁₆ₐₘₚₛ. In the example depicted in FIG. 9A, ΔA₁=A₀ₐₘₚₛ−A₂ₐₘₚₛ. This measurement requires the etching of two test wafers at constant inner coil currents of 0 amps and 2 amps respectively.

The twelve measured distributions at the twelve inner coil current values of FIG. 9A and the plasma distribution change ΔA₁ are used to construct all the remaining A₁'s at the eighteen remaining current values depicted in FIG. 9B (block 806 of FIGS. 8A-8B). This construction is performed by interpolating between the twelve measured A₁'s of FIG. 9A at intervals of ΔIᵢₙₙₑᵣ by adding (or subtracting) the appropriate multiple of ΔA₁ from each distribution A₁.

Next, in block 820 of FIGS. 8A-8B, a set of plasma distributions A₂ are measured for all discrete values of Iₒᵤₜₑᵣ in a predetermined range (e.g., −24 amps to +24 amps). (The subscript “2” refers to the outer coil current). This is carried out as follows. First, in block 822, a reduced number of outer coil current plasma distributions A₂ are measured at a small number (e.g., twelve) of widely spaced values of Iₒᵤₜₑᵣ spanning the chosen range. One example of this step is depicted in FIG. 9C, in which the chosen range is −24 amps to +24 amps, and the values of Iₒᵤₜₑᵣ occur in steps of ΔIₒᵤₜₑᵣ=4 amps, so that only twelve measurements are taken. Each of the twelve measurements is carried out by etching a test wafer while holding the current on the inner coil at one of the six values of Iₒᵤₜₑᵣ and then deducing the two-dimensional plasma distribution A₂ from the etch depth distribution on the test wafer, and storing the corresponding two-dimensional distribution A₂. Then, in block 824, a measurement is made to determine the change ΔA₂ in A₂ for a predetermined incremental change ΔIₒᵤₜₑᵣ=4 amps in the coil current Iₒᵤₜₑᵣ. In one embodiment, it is assumed that the change ΔA₂ is the same regardless of location within the range −24 amps to +24 amps. The change ΔA₂ may be found by subtracting any two measured distributions A₂ generated by coil currents that differ by 4 amps. For example, ΔA₂=B₈ₐₘₚₛ−B₁₆ₐₘₚₛ. In the example depicted in FIG. 9C, ΔA₂=B₀ₐₘₚₛ−B₂ₐₘₚₛ. This measurement requires the etching of two test wafers at constant outer coil currents of 0 amps and 2 amps respectively.

The twelve measured distributions A₂ at the twelve outer coil current values of FIG. 9C and the distribution change ΔA₂ are used to construct all the remaining A₂'s at the eighteen remaining current values depicted in FIG. 9D (block 826 of FIGS. 8A-8B). This construction is performed by interpolating between the measured twelve A₂'s of FIG. 9C at intervals of ΔIₒᵤₜₑᵣ by adding (or subtracting) ΔA₂ from each distribution.

In block 830 of FIGS. 8A-8B, a set of combined plasma distributions C are constructed as sums of all possible pairings of A₁'s with A₂'s, where each C is defined as C=A₁+A₂. For each C, an average distribution Aₐᵥₑ is computed as the average plasma density of C (block 835). This computation may be carried out in one embodiment in accordance with the following equation:

$${A}_{ave} = {\sum }_{j = 1}^{n} {\int }_{0}^{R} {\int }_{0}^{2 π} \cdot {A}_{j} \cdot d r \cdot d θ$$

where dr is an incremental radius, dθ is an incremental angle in cylindrical coordinates and R is the radius of the workpiece, and j runs from 1 (inner coil) to 2 (outer coil).

In block 840, a variance function is defined as the standard deviation of C from Aₐᵥₑ. The variance function may be defined in one embodiment in accordance with the following equation:

$$σ = {[ \frac{1}{{A}_{ave}} {\int }_{0}^{R} {\int }_{0}^{2 π} \frac{1}{R} {( {\sum }_{j = 1}^{n} {A}_{j} - {A}_{ave} )}^{2} d r \cdot d θ ]}^{1 / 2}$$

The foregoing equations use the more general notation in which j is the index of each coil running from 1 to n. In the foregoing example, there are only two coils, an inner coil and an outer coil, so that n=2. However, in the more general case, the number of coils, n, may be any integer greater than 1.

In block 845, the processor 130 computes the variances a for all possible combinations of n plasma distributions Aⱼ and stores the results in memory, and then searches the memory for the particular “optimum” combination of n Aⱼ's for which the variance function a is minimum. In block 850, the processor 130 looks up in memory for the n coil currents corresponding to the optimum combination of n Aⱼ's, and chooses those currents as the optimum coil currents. In the present example employing only and inner coil and outer coil, n=2, and each combination of distribution is a sum of a pair of distributions A₁+A₂ produced by corresponding coil currents Iᵢₙₙₑᵣ, Iₒᵤₜₑᵣ. The processor 130 searches the results of the foregoing search for the coil current pair Iᵢₙₙₑᵣ′, Iₒᵤₜₑᵣ′ corresponding to the particular combination distribution A₁+A₂ having the minimum variance σ. In block 855, a wafer or workpiece is processed in the plasma reactor by constantly maintaining the coil currents at the designated optimum values Iᵢₙₙₑᵣ′, Iₒᵤₜₑᵣ′.

While the foregoing is directed to embodiments. of the present invention, other and further embodiments of the invention may be devised without departing from the basic scope thereof, and the scope thereof is determined by the claims that follow.

What is claimed is:

1. A method of processing a workpiece in a chamber of a plasma reactor having a set of plural electromagnet coils, comprising:
selecting plural predetermined plasma density distributions relative to a workpiece surface, said predetermined plasma density distributions corresponding to different sets of D.C. currents in said coils;
flowing a process gas into the chamber and generating a plasma in the chamber; and
switching plasma in said chamber between said predetermined plasma density distributions by switching D.C. currents through said coils between said different sets of D.C. currents.

2. The method of claim 1 wherein said predetermined plasma density distributions have different non-uniformities that are at least partially mutually compensating.

3. The method of claim 1 further comprising time-weighting said predetermined plasma density distributions by controlling the respective time durations said plasma spends in the respective ones of said predetermined plasma density distributions.

4. The method of claim 3 further comprising adjusting said time-weighting to optimize uniformity of process rate distribution at said workpiece surface.

5. The method of claim 4 wherein:
said processing comprises carrying out one of: (a) an etch process, (b) a deposition process; and
the uniformity of process rate distribution comprises uniformity of one of: (a) etch rate distribution, (b) deposition rate distribution.

6. The method of claim 5 wherein said plural predetermined plasma density distributions are two-dimensional and wherein said different non-uniformities of said predetermined distributions comprise azimuthal non-uniformities and radial non-uniformities.

7. The method of claim 6 wherein said azimuthal non-uniformities of said predetermined distributions are at least partially mutually compensating and said radial non-uniformities of said predetermined distributions are at least partially mutually compensating.

8. The method of claim 5 wherein said plural predetermined plasma density distributions comprise a first distribution having a radial component that is center-high and a second distribution having a radial component that is center-low.

9. The method of claim 1 wherein said switching D.C. currents in said coils between said different sets of D.C. currents comprises changing the currents in all of said coils for each transition between the predetermined distributions.

10. The method of claim 1 wherein said switching D.C. currents in said coils between said different sets of D.C. currents comprises changing (a) the magnitudes of the currents in at least some of said coils and (b) the polarities of the currents in at least some of said coils.

11. The method of claim 1 wherein said switching D.C. currents in said coils between said different sets of D.C. currents comprises maintaining a constant D.C current in a least one of said coils while changing the currents in remaining one or ones of said coils for each transition between the predetermined distributions.

12. The method of claim 1 wherein said switching D.C. currents in said coils between said different sets of D.C. currents comprises reversing polarities of the currents in all of said coils for each transition between the predetermined distributions.

13. The method of claim 4 wherein said adjusting said time-weighting comprises:
defining said predetermined distributions as a set Aⱼ where j is a real number from 1 to n, where n is the number of said predetermined distributions and defining a set of time weights aⱼ, each aⱼ corresponding to the time duration said plasma spends in the corresponding predetermined distribution Aⱼ;
defining a time-weighted distribution A=a₁ A₁+a₂ A₂+ . . . +aₙ Aₙ;
searching for an optimum set of time weights coefficients a₁, a₂, . . . aₙ, that produces a time weighted distribution A having the least plasma distribution variance; and
performing said switching so that respective time durations spent by the plasma in the respective predetermined distributions corresponds to said optimum set of time weights.

14. The method of claim 13 wherein n=2.

15. Electronically-readable storage media storing instructions for carrying out the method of any one of claims 1-14.

16. A method of processing a workpiece in a chamber of a plasma reactor having a set of plural electromagnet coils comprising at least inner and outer coils for carrying respective coil currents Iᵢₙₙₑᵣ, Iₒᵤₜₑᵣ, comprising:
choosing different 2-D plasma distributions Aⱼ(r,θ) having mutually complementary behaviors, each Aⱼ(r,θ) produced by a different pair of known coil currents Iᵢₙₙₑᵣ^{j}, Iₒᵤₜₑᵣ^{j} in said inner and outer coils respectively;
defining unknown time weighting coefficients aⱼ and a combined time weighted plasma distribution A_{comb}=a₁ A₁+a₂ A₂+ . . . +aₙ Aₙ
defining an average plasma density value Aₐᵥₑ as a function of all the Aⱼ
defining a variance function as the standard deviation of A_{comb} from Aₐᵥₑ as a function of the chosen distributions Aⱼ's, the unknown time weighting coefficients aⱼ's and Aₐᵥₑ;
searching for an optimum set of time weighting coefficients aⱼ′ that minimizes the variance function; and
during plasma processing of a workpiece in said chamber, operating the coil currents to switch the plasma distribution among the chosen distributions Aⱼ such that the time spent in a particular plasma distribution Aⱼ is proportional to the corresponding one of said optimum time weighting coefficients aⱼ′.

17. The method of claim 16 wherein said operating the coil currents comprises switching between the chosen distributions using mutually exclusive duty cycles.

18. The method of claim 16 wherein said operating the coil currents comprises maintaining one of the coil currents constant while periodically switching the other coil current.

19. The method of claim 16 wherein said operating the coil currents comprises switching between the chosen distributions comprises reversing the polarities of said coil currents.
